(19) United States
(12) Patent Application Publication
(10) Pub. No.: US 2024/0019467 A1
(43) Pub. Date: Jan. 18, 2024

(54) FREQUENCY ESTIMATION IN A POWER SYSTEM

(71) Applicants: Seyed Soroush Karimi Madahi, Tehran (IR); Hossein Askarian Abyaneh, Tehran (IR); Farzad Razavi, Qazvin (IR); Mohammad Parpaei, Qazvin (IR); Davood Yoosefian, Gonabad (IR)

(72) Inventors: Seyed Soroush Karimi Madahi, Tehran (IR); Hossein Askarian Abyaneh, Tehran (IR); Farzad Razavi, Qazvin (IR); Mohammad Parpaei, Qazvin (IR); Davood Yoosefian, Gonabad (IR)

(73) Assignees: Seyed Soroush Karimi Madahi, Tehran, OT (IR); Hossein Askarian Abyaneh, Tehran, OT (IR); Farzad Razavi, Qazvin, OT (IR); Mohammad Parpaei, Qazvin, OT (IR); Davood Yoosefian, Gonabad, OT (IR); Amirkabir University of Technology, Tehran, OT (IR); VEBKO Amirkabir, Tehran, OT (IR)

(21) Appl. No.: 18/365,152

(22) Filed: Aug. 3, 2023

Related U.S. Application Data
(63) Continuation-in-part of application No. PCT/IB2022/050565, filed on Jan. 22, 2022.
(60) Provisional application No. 63/144,987, filed on Feb. 3, 2021.

(51) Int. Cl. G01R 19/25; G01R 23/12; G01R 31/08

(52) U.S. Cl. CPC G01R 19/2513; G01R 23/12; G01R 31/088

(57) ABSTRACT

A method for frequency estimation in a power system. The method includes detecting a condition of the power system, applying a first estimation process to a voltage signal of the power system responsive to a normal condition being detected, and applying a second estimation process to a current signal of the power system responsive to a fault condition being detected. The condition of the power system is detected utilizing a protective device. The condition of the power system includes one of a normal condition and a fault condition.

### CROSS-REFERENCE TO RELATED APPLICATION

This application is a continuation-in-part of PCT/IB2022/050565 filed Jan. 22, 2022, which claims the benefit of priority from U.S. Provisional Patent Application Ser. No. 63/144,987, filed on Feb. 3, 2021, and entitled “ESTIMATING THE FREQUENCY OF POWER SYSTEMS UNDER NORMAL AND FAULT CONDITIONS,” which are both incorporated herein by reference in their entirety.

### TECHNICAL FIELD

The present disclosure generally relates to power systems, and particularly, to frequency estimation in power systems.

### BACKGROUND

Frequency is a key parameter for monitoring, control, and protection of power systems. An imbalance between consumption and generation in a power system may deviate a frequency of a power system from nominal frequency of power system. Electrical devices may efficiently operate in nominal frequency. Hence, deviation in frequency of power systems from nominal value may damage electrical devices. Moreover, frequency plays a major role in monitoring and protective devices such as phasor measurement unit (PMU), under-frequency, and rate of change of frequency relays. Therefore, an accurate frequency estimation is of paramount importance for protection of power systems.

Existing methods may use voltage signal for frequency estimation. However, in some conditions, particularly when a fault occurs close to a relay bus, using voltage signal may cause errors. When a close-in fault occurs, some transients (called subsidence transients) may appear in a secondary voltage of coupling capacitor voltage transformer (CCVT) due to sudden primary voltage drop of CCVT. Subsidence transients typically may consist of oscillatory decaying high frequency, oscillatory decaying low frequency, and decaying DC components. Besides, fault current may include an asymmetrical wave that includes symmetrical wave and transient decaying DC. In conventional methods, eliminating an impact of decaying DC component may be limited to nominal conditions, that is, assumption of nominal frequency instead of actual frequency.

There is, therefore, a need for a frequency estimation method that is not affected by decaying DC component under fault and normal conditions. Moreover, there is a need for a method to mitigate an impact of decaying DC component in off-nominal conditions.

### SUMMARY

This summary is intended to provide an overview of the subject matter of the present disclosure, and is not intended to identify essential elements or key elements of the subject matter, nor is it intended to be used to determine the scope of the claimed implementations. The proper scope of the present disclosure may be ascertained from the claims set forth below in view of the detailed description below and the drawings.

In one general aspect, the present disclosure describes an exemplary method for frequency estimation in a power system. An exemplary method may include detecting a condition of the power system, applying a first estimation process to a voltage signal of the power system responsive to a normal condition being detected, and applying a second estimation process to a current signal of the power system responsive to a fault condition being detected. An exemplary condition of the power system may be detected utilizing a protective device. An exemplary condition of the power system may include one of a normal condition and a fault condition.

In an exemplary embodiment, applying the first estimation process may include obtaining a plurality of voltage samples by sampling the voltage signal and obtaining an estimated normal frequency of the power system based on the plurality of voltage samples. In an exemplary embodiment, the plurality of voltage samples may be obtained utilizing the protective device. In an exemplary embodiment, the estimated normal frequency may be obtained utilizing one or more processors. In an exemplary embodiment, obtaining the estimated normal frequency may include generating a first plurality of shifted voltage samples from the plurality of voltage samples, generating a plurality of filtered voltage samples by filtering the first plurality of shifted voltage samples, generating a second plurality of shifted voltage samples from the plurality of filtered voltage samples, obtaining a root xᵣ of a first polynomial based on the second plurality of shifted voltage samples, and calculating the estimated normal frequency according to an operation defined by

$$\frac{2}{N π} {cos}^{- 1} {x}_{r} .$$

In an exemplary embodiment, generating the first plurality of shifted voltage samples may include multiplying an n^{th} sample of the plurality of voltage samples by e^{jω}^{ₙₒₘ}ⁿ, where nε[0, N−1], N is a number of the plurality of voltage samples, and ωₙₒₘ is a nominal angular frequency of the power system. In an exemplary embodiment, generating the second plurality of shifted voltage samples may include multiplying an n^{th} sample of the plurality of filtered voltage samples by e^{-jω}^{ₙₒₘ}ⁿ.

In an exemplary embodiment, applying the second estimation process may include obtaining a plurality of current samples by sampling the current signal and obtaining an estimated fault frequency of the power system. In an exemplary embodiment, the plurality of current samples may be obtained utilizing the protective device. In an exemplary embodiment, the estimated fault frequency may be obtained utilizing the one or more processors. In an exemplary embodiment, obtaining the estimated fault frequency may include generating a plurality of filtered current samples by filtering the plurality of current samples, obtaining a root yᵣ of a second polynomial based on the plurality of filtered current samples, and calculating the estimated fault frequency according to an operation defined by

$$\frac{2}{N π} {cos}^{- 1} {y}_{r} .$$

In an exemplary embodiment, filtering each of the first plurality of shifted voltage samples and the plurality of current samples may include obtaining a first plurality of weights of a filter. In an exemplary embodiment, obtaining the first plurality of weights may include solving an optimization problem. An exemplary objective function of the optimization problem may include a magnitude of a frequency response of the filter at a zero angular frequency. An exemplary m^{th} constraint of the optimization problem may include a magnitude of the frequency response at an angular frequency ωₘ being less than a magnitude threshold, where mε[1, M], M is a number of constraints in the optimization problem, and the angular frequency ωₘ is larger than a frequency threshold ωₜₕ.

In an exemplary embodiment, filtering each of the first plurality of shifted voltage samples and the plurality of current samples may further include obtaining a second plurality of weights. In an exemplary embodiment, the second plurality of weights may be obtained according to an operation defined by h(n)*h(n), where h(n) is an n^{th} weight of the first plurality of weights and * is a convolution operator.

In an exemplary embodiment, solving the optimization problem may include setting a value of the angular frequency ωₘ to

$${ω}_{th} + ( m - 1 ) \frac{π}{{f}_{s}} ,$$

where fₛ is a sampling frequency of the protective device. In an exemplary embodiment, setting the value of the angular frequency ωₘ may include setting the value of the frequency threshold ωₜₕ to 2ωₙₒₘ. In an exemplary embodiment, solving the optimization problem may include setting the magnitude threshold to 10⁻⁵.

In an exemplary embodiment, detecting the condition of the power system may include detecting one of the fault condition responsive to an electrical fault being detected in the power system or the normal condition responsive to the electrical fault not being detected.

Other exemplary systems, methods, features and advantages of the implementations will be, or will become, apparent to one of ordinary skill in the art upon examination of the following figures and detailed description. It is intended that all such additional systems, methods, features and advantages be included within this description and this summary, be within the scope of the implementations, and be protected by the claims herein.

### BRIEF DESCRIPTION OF THE DRAWINGS

The drawing figures depict one or more implementations in accord with the present teachings, by way of example only, not by way of limitation. In the figures, like reference numerals refer to the same or similar elements.

FIG. 1A shows a flowchart of a method for frequency estimation in a power system, consistent with one or more exemplary embodiments of the present disclosure.

FIG. 1B shows a flowchart of a method for applying a first estimation process to a voltage signal of a power system, consistent with one or more exemplary embodiments of the present disclosure.

FIG. 1C shows a flowchart of a method for obtaining an estimated frequency, consistent with one or more exemplary embodiments of the present disclosure.

FIG. 1D shows a flowchart of a method for filtering a first plurality of shifted voltage samples, consistent with one or more exemplary embodiments of the present disclosure.

FIG. 1E shows a flowchart of a method for applying a second estimation process on a current signal of a power system, consistent with one or more exemplary embodiments of the present disclosure.

FIG. 1F shows a flowchart of a method for obtaining an estimated frequency of a power system, consistent with one or more exemplary embodiments of the present disclosure.

FIG. 2 shows a schematic of a protective device for frequency estimation in a power system, consistent with one or more exemplary embodiments of the present disclosure.

FIG. 3 shows a high-level functional block diagram of a computer system, consistent with one or more exemplary embodiments of the present disclosure.

FIG. 4 shows a graph of frequency estimation error in a power system for various fundamental frequencies, consistent with one or more exemplary embodiments of the present disclosure.

FIG. 5 shows a graph of frequency estimation error in a power system for signals corrupted by various harmonic orders, consistent with one or more exemplary embodiments of the present disclosure.

FIG. 6 shows a graph of frequency estimation error in a power system for current signal corrupted by harmonic and decaying direct current components, consistent with one or more exemplary embodiments of the present disclosure.

### DETAILED DESCRIPTION

In the following detailed description, numerous specific details are set forth by way of examples in order to provide a thorough understanding of the relevant teachings. However, it should be apparent that the present teachings may be practiced without such details. In other instances, well known methods, procedures, components, and/or circuitry have been described at a relatively high-level, without detail, in order to avoid unnecessarily obscuring aspects of the present teachings.

The following detailed description is presented to enable a person skilled in the art to make and use the methods and devices disclosed in exemplary embodiments of the present disclosure. For purposes of explanation, specific nomenclature is set forth to provide a thorough understanding of the present disclosure. However, it will be apparent to one skilled in the art that these specific details are not required to practice the disclosed exemplary embodiments. Descriptions of specific exemplary embodiments are provided only as representative examples. Various modifications to the exemplary implementations will be readily apparent to one skilled in the art, and the general principles defined herein may be applied to other implementations and applications without departing from the scope of the present disclosure. The present disclosure is not intended to be limited to the implementations shown, but is to be accorded the widest possible scope consistent with the principles and features disclosed herein.

Herein is disclosed an exemplary method for frequency estimation in a power system under fault and normal conditions. An exemplary method may include determining a condition of a power system. In a normal condition, an exemplary voltage signal of the power system may be frequency shifted, passed through a filter, and frequency shifted back. An exemplary system of equations may be constructed from resulting samples, and an exemplary decaying direct current (DC) component and various harmonic components of the voltage signal may be removed by solving the system of equations, resulting in a third-degree polynomial. A root of an exemplary third-degree polynomial may include an estimated frequency of a power system under the normal condition. Under a fault condition, an exemplary current signal of the power system may be passed through a filter. An exemplary system of equations may be constructed from output samples of the filter, and an exemplary decaying DC component and different harmonics of the current signal may be removed by solving the system of equations, resulting in a third-degree polynomial. A root of an exemplary third-degree polynomial may include an estimated frequency of a power system under the fault condition.

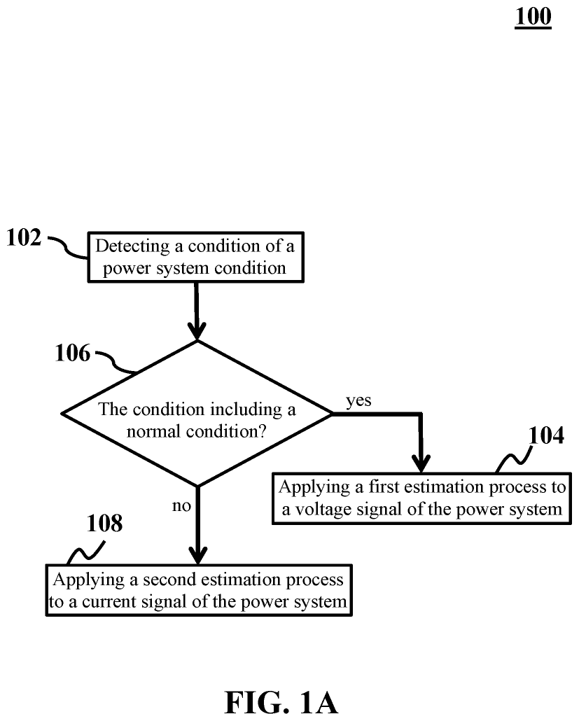

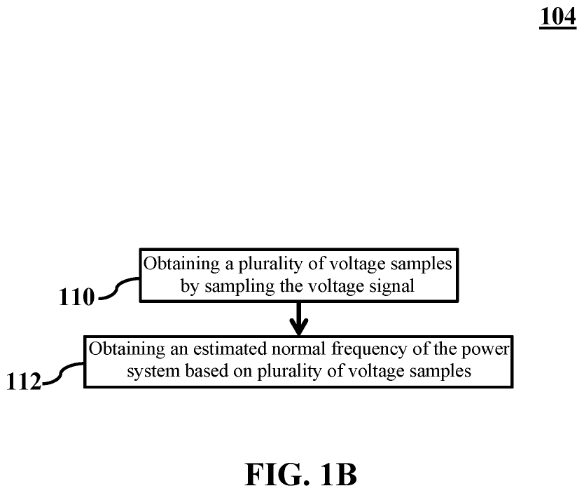

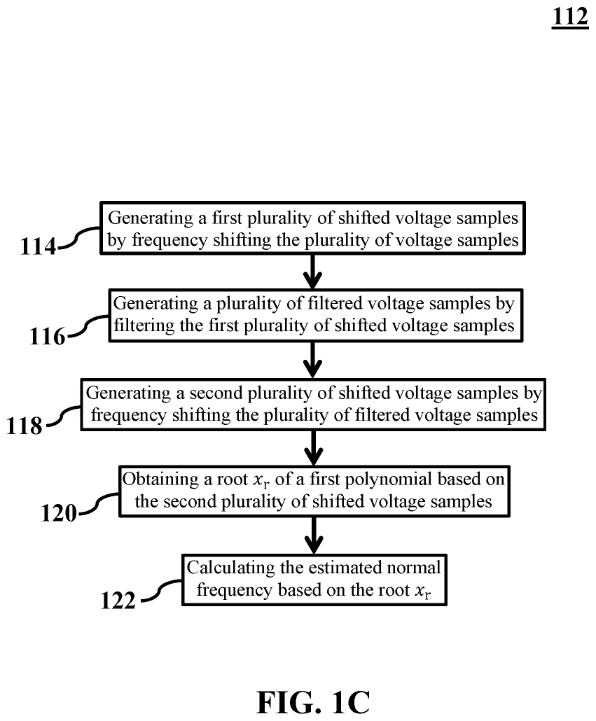

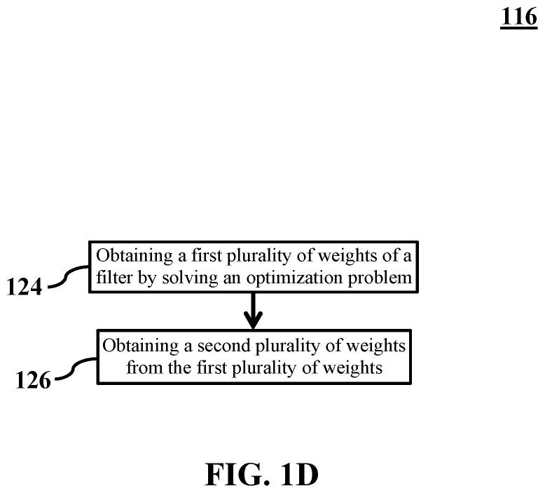

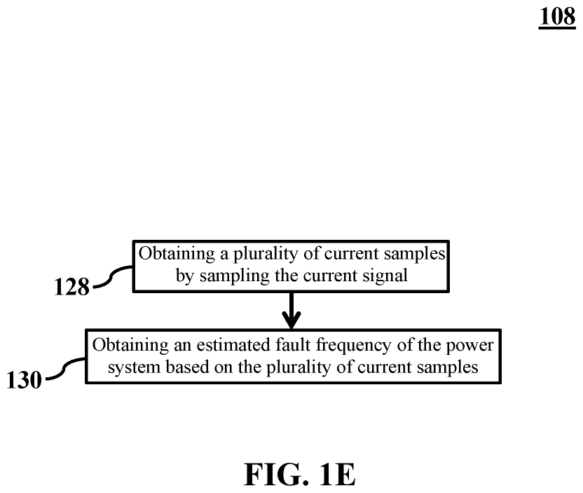

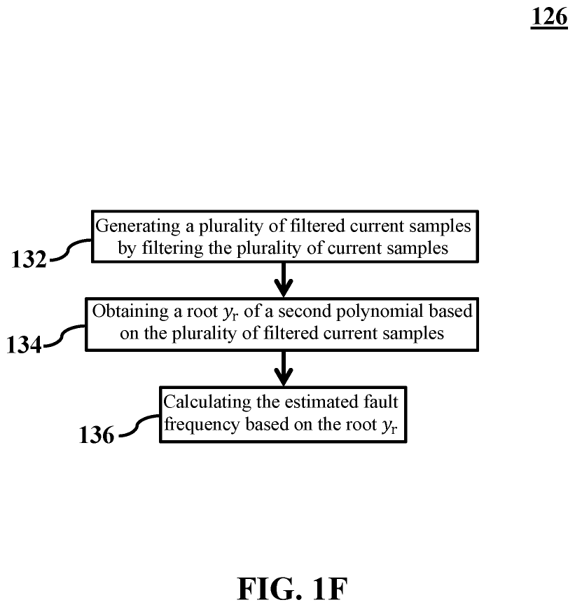

FIG. 1A shows a flowchart of a method for frequency estimation in a power system, consistent with one or more exemplary embodiments of the present disclosure. In an exemplary embodiment, a method 100 may include detecting a condition of a power system (step 102), applying a first estimation process to a voltage signal of the power system (step 104) responsive to a normal condition being detected (step 106, yes), and applying a second estimation process to a current signal of the power system (step 108) responsive to a fault condition being detected (step 106, no). An exemplary condition of the power system may be detected utilizing a protective device. An exemplary condition of the power system may include one of a normal condition and a fault condition.

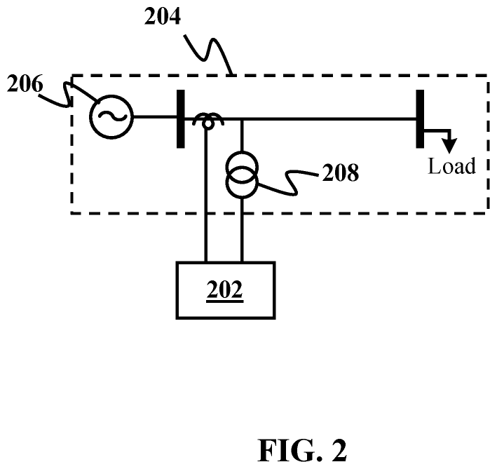

FIG. 2 shows a schematic of a protective device for frequency estimation in a power system, consistent with one or more exemplary embodiments of the present disclosure. Referring to FIGS. 1A and 2, in an exemplary embodiment, different steps of method 100 may be implemented utilizing a protective device 202. In an exemplary embodiment, protective device 202 may refer to a piece of electrical equipment that may be applied to power system 204 to detect abnormal and intolerable conditions and to initiate appropriate corrective actions. In an exemplary embodiment, protective device 202 may include a protective relay or a phasor measurement unit. In an exemplary embodiment, power system 204 may be designed to supply a load with electric power generated by a power generator 206. In an exemplary embodiment, protective device 202 may utilize a voltage transformer 208 to protect power system 204. In an exemplary embodiment, voltage transformer 208 may include a coupling capacitor voltage transformer.

For further detail with respect to step 102, in an exemplary embodiment, detecting the condition of power system 204 may include detecting one of the fault condition responsive to an electrical fault being detected in power system 204 or the normal condition responsive to the electrical fault not being detected. An exemplary electrical fault may be referred to as any abnormalities (such as signal distortion) in voltage signals or current signals in power system 204. In an exemplary embodiment, detecting an electrical fault may be performed by a root mean square calculation-based fault detection method.

For further detail with respect to step 104, FIG. 1B shows a flowchart of a method for applying a first estimation process to a voltage signal of a power system, consistent with one or more exemplary embodiments of the present disclosure. Referring to FIGS. 1B and 2, in an exemplary embodiment, applying the first estimation process may include obtaining a plurality of voltage samples by sampling the voltage signal (step 110) and obtaining an estimated normal frequency of power system 204 based on the plurality of voltage samples (step 112).

In further detail regarding step 110, in an exemplary embodiment, the plurality of voltage samples may be obtained utilizing protective device 202. In an exemplary embodiment, the plurality of voltage samples may be sampled during one cycle of nominal frequency of power system 204, that is, a sampling window may be equal to Tₙₒₘ=1/fₙₒₘ, where fₙₒₘ is a nominal frequency of power system 204. An exemplary sampling frequency of protective device 202 may be equal to fₛ=Nfₙₒₘ, where N is a number of samples in one cycle. In an exemplary normal condition of power system 204, a voltage signal may not be distorted by abnormalities such as decaying direct current (DC) component. As a result, an exemplary voltage signal may be more stable than a current signal of power system 204 for frequency estimation.

For further detail with respect to step 112, FIG. 1C shows a flowchart of a method for obtaining an estimated normal frequency, consistent with one or more exemplary embodiments of the present disclosure. Referring to FIGS. 1C and 2, in an exemplary embodiment, obtaining the estimated normal frequency may include generating a first plurality of shifted voltage samples by frequency shifting the plurality of voltage samples (step 114), generating a plurality of filtered voltage samples by filtering the first plurality of shifted voltage samples (step 116), generating a second plurality of shifted voltage samples by frequency shifting the plurality of filtered voltage samples (step 118), obtaining a root xᵣ of a first polynomial based on the second plurality of shifted voltage samples (step 120), and calculating the estimated normal frequency based on the root xᵣ (step 122). In an exemplary embodiment, the estimated normal frequency may be obtained utilizing a processor of protective device 202.

In further detail with regard to step 114, in an exemplary embodiment, generating the first plurality of shifted voltage samples may include multiplying an n^{th} sample of the plurality of voltage samples by e^{jω}^{ₙₒₘ}ⁿ, where n ε[0, N−1] and ωₙₒₘ=2πfₙₒₘ is a nominal angular frequency of power system 204. An exemplary voltage signal may include H significant harmonics. An exemplary frequency shifting may shift frequencies of h^{th} harmonic of voltage signal to hωᵣ+ωₙₒₘ and −hωᵣ+ωₙₒₘ, where ωᵣ is a frequency of power system 204 to be estimated and h∞[1, H]. Therefore, in an exemplary embodiment, hωᵣ+ωₙₒₘ and −hωᵣ+ωₙₒₘ may include frequency component of (h−1)^{th} and (h+1)^{th} order harmonics of the voltage signal, respectively. In an exemplary embodiment, for h=1, −hωᵣ+ωₙₒₘ is about zero and h⋅ᵣ+ωₙₒₘ is about a frequency of a second-order harmonic of the voltage signal, that is, ωᵣ+ωₙₒₘ≈2ωₙₒₘ. Hence, in an exemplary embodiment, a filter with a cutoff frequency of 2ωₙₒₘ may be able to filter second and higher order harmonics of the voltage signal.

For further detail regarding step 116, FIG. 1D shows a flowchart of a method for filtering a first plurality of shifted voltage samples, consistent with one or more exemplary embodiments of the present disclosure. In an exemplary embodiment, filtering the first plurality of shifted voltage samples may include obtaining a first plurality of weights of a filter by solving an optimization problem (step 124) and obtaining a second plurality of weights from the first plurality of weights (step 126).

In further detail with respect to step 124, in an exemplary embodiment, obtaining the first plurality of weights may include solving an optimization problem. An exemplary objective function of the optimization problem may include a magnitude of a frequency response of the filter at a zero angular frequency, that is,

$$\frac{2}{N} {\sum }_{n = 0}^{N - 1} h ( n ) ,$$

where h(n) is an n^{th} weight of the plurality of weights. An exemplary m^{th} constraint of the optimization problem may include a magnitude of the frequency response at an angular frequency ωₘ being less than a magnitude threshold z, where mε[1, M], M is a number of constraints in the optimization problem, and the angular frequency ωₘ is larger than a frequency threshold ωₜₕ. In other words, an exemplary m^{th} constraint may be defined according to the following:

{square root over ((Σₙ₌₀^{N-1}h(n) cos (ωₘn))²+(Σₙ₌₀^{N-1}h(n) sin (ωₘn))²)}≤z,ωₘ≥ωₜₕ Inequation (1)

Referring to FIGS. 1D and 2, in an exemplary embodiment, solving the optimization problem may determine the plurality of weights h(n), ∀n. An exemplary optimization problem may include a convex optimization problem. Therefore, an exemplary optimization problem may be solved via interior point methods. An exemplary angular frequency of power system 204 may be continuous, resulting in infinitely many constraints in the optimization problem. To avoid infinitely many constraints, an exemplary angular frequency may be discretized and one constraint for each discrete angular frequency may be added to the optimization problem. An exemplary angular frequency may be discretized in a range of 0 to

$$\frac{π}{2} in \frac{{f}_{s}}{2}$$

intervals, each with a length of

$$\frac{π}{{f}_{s}} .$$

Therefore, solving an exemplary optimization problem may include setting a value of angular frequency ωₘ to

$${ω}_{th} + ( m - 1 ) \frac{π}{{f}_{s}} .$$

In an exemplary embodiment, frequency threshold ωₜₕ may be set to remove second and higher order harmonics of the voltage signal. Therefore, in an exemplary embodiment, setting a value of angular frequency ωₘ may include setting the value of frequency threshold ωₜₕ to 2ωₙₒₘ. In an exemplary embodiment, since a difference of frequency ωᵣ and nominal angular frequency ωₙₒₘ may be small, setting the value of frequency threshold ωₜₕ to 2ωₙₒₘ may result in removing second and higher order harmonics of the voltage signal. An exemplary optimization problem may be infeasible when a magnitude of the frequency response at angular frequency ωₘ is set to zero. In other words, in an exemplary embodiment, the first plurality of weights that result in zero magnitude of the frequency response at angular frequency ωₘ may not exist. To resolve infeasibility, in an exemplary embodiment, magnitude of the frequency response at angular frequency ωₘ may be constrained to a small positive value, that is, magnitude threshold z. In an exemplary embodiment, magnitude threshold z may be set to 10⁻⁵.

For further detail regarding to step 126, in an exemplary embodiment, filtering the first plurality of shifted voltage samples may further include obtaining a second plurality of weights. An exemplary filter may include a low-pass filter. An efficiency of an exemplary low-pass filter may be enhanced by applying a self-convolution operation on a plurality of weights of the low-pass filter. In other words, a ratio of frequency response magnitudes of the low-pass filter in passband and stopband may increase by applying a self-convolution operation on a plurality of weights of the low-pass filter. An exemplary second plurality of weights may include a result of self-convolution operation on the first plurality of weights, that is, the second plurality of weights may be obtained according to an operation defined by h(n)*h(n), where * is a convolution operator.

Referring again to FIGS. 1C and 2, in an exemplary embodiment, step 118 may include generating the second plurality of shifted voltage samples. An exemplary plurality of filtered voltage samples may include baseband digital samples. Therefore, an exemplary output of the filter may be shifted back to a signal with angular frequency ωᵣ by frequency shifting the plurality of filtered voltage samples. In an exemplary embodiment, frequency shifting the plurality of filtered voltage samples may include multiplying an n^{th} sample of the plurality of filtered voltage samples by e^{-jω}^{ₙₒₘ}ⁿ. In an exemplary embodiment, details of generating the second plurality of shifted voltage samples may be similar to generating the first plurality of shifted voltage samples discussed in step 114.

In further detail with regard to step 120, in an exemplary embodiment, a frequency of power system 204 may be estimated by constructing a system of equations from the second plurality of shifted voltage samples. In an exemplary embodiment, an n^{th} sample V(n) of the second plurality of shifted voltage samples may be equal to

$$\frac{{A}_{1}}{2} {e}^{j ( - {ω}_{r} n + {θ}_{1} )} + \frac{{A}_{2}}{2} {e}^{j ( - 2 {ω}_{r} n + {θ}_{2} )} ,$$

where A₁ and A₂ correspond to magnitudes of a first and a second order harmonic of the voltage signal, and θ₁ and θ₂ correspond to phases of the first and the second order harmonic. An exemplary system of equations may be constructed from samples

$$V ( n + \frac{N}{2} ) , V ( n - \frac{N}{2} ) , V ( n + \frac{N}{4} ) , and V ( n - \frac{N}{4} ) .$$

Solving an exemplary system of equations may eliminate values of A₁, A₂, θ₁, and θ₂. By defining

$$x = cos \frac{N}{4} {ω}_{r} ,$$

solving an exemplary system of equations may include obtaining a root xᵣ of a first polynomial defined by the following:

$$2 Im \{ V ( n - \frac{N}{2} ) \} {x}^{3} - 2 {μ}_{1} {x}^{2} - ( {μ}_{1} + Im \{ V ( n - \frac{N}{2} ) \} ) x + {μ}_{1} + {μ}_{2} , where {μ}_{1} = \frac{1}{2} ( Im \{ V ( n + \frac{N}{4} ) \} + Im \{ V ( n - \frac{N}{4} ) \} ) , {μ}_{2} = \frac{1}{4} ( Im \{ V ( n + \frac{N}{2} ) \} + Im \{ V ( n - \frac{N}{2} ) \} + 2 Im \{ V ( n ) \} ) , \qquad Equation ( 1 )$$

and Im{V(.)} returns an imaginary part of V(.). An exemplary third-degree polynomial may include at least one real root. An exemplary real root of the first polynomial in Equation (1) may include a value in [−1,1]. An exemplary root of the first polynomial may be obtained by Cardan's method.

For further detail with respect to step 122, in an exemplary embodiment, the estimated normal frequency may be obtained from root xᵣ. In an exemplary embodiment, an independent variable x of the first polynomial may be obtained by change of a variable, that is, an angular frequency ωᵣ=2πfᵣ of power system 204, where fᵣ is a fundamental frequency of power system 204. As previously stated, an exemplary change of variable is

$$x = cos \frac{N}{4} {ω}_{r} .$$

As a result, an exemplary estimated normal frequency may be obtained according to an operation defined by

$$\frac{2}{N π} {cos}^{- 1} {x}_{r} .$$

Referring again to FIGS. 1A and 2, in an exemplary embodiment, step 108 may include applying the second estimation process on the current signal of power system 204 responsive to a fault condition being detected in power system 204. FIG. 1E shows a flowchart of a method for applying a second estimation process on a current signal of a power system, consistent with one or more exemplary embodiments of the present disclosure. Referring to FIGS. 1E and 2, in an exemplary embodiment, applying the second estimation process may include obtaining a plurality of current samples by sampling the current signal (step 128) and obtaining an estimated fault frequency of power system 204 (step 130).

In further detail regarding step 128, in an exemplary embodiment, the plurality of current samples may be obtained utilizing protective device 202. In an exemplary embodiment, the plurality of current samples may be sampled during one cycle of nominal frequency of power system 204, that is, a sampling window may be equal to Tₙₒₘ=1/fₙₒₘ. An exemplary sampling frequency of protective device 202 may be equal to fₛ=Nfₙₒₘ. In an exemplary fault condition of power system 204, a voltage signal may be distorted by abnormalities such as oscillatory decaying high frequency, oscillatory decaying low frequency, and decaying DC components. In contrast, an exemplary current signal in a fault condition may include a decaying DC component. As a result, an exemplary current signal may be distorted less than a voltage signal in a fault condition. Therefore, in an exemplary fault condition, utilizing the current signal instead of the voltage signal may result in a more precise frequency estimation.

For further detail with regard to step 130, FIG. 1F shows a flowchart of a method for obtaining an estimated fault frequency of a power system, consistent with one or more exemplary embodiments of the present disclosure. Referring to FIGS. 1F and 2, in an exemplary embodiment, obtaining the estimated fault frequency may include generating a plurality of filtered current samples by filtering the plurality of current samples (step 132), obtaining a root yᵣ of a second polynomial based on the plurality of filtered current samples (step 134), and calculating the estimated fault frequency based on the root yᵣ (step 136). In an exemplary embodiment, the estimated fault frequency may be obtained utilizing the processor of protective device 202.

In further detail with respect to step 132, in an exemplary embodiment, filtering the plurality of current samples may include obtaining a first plurality of weights of a filter. In an exemplary embodiment, filtering the plurality of current samples may be similar to filtering the first plurality of shifted voltage samples in step 116. In an exemplary embodiment, both the plurality of current samples and the first plurality of shifted voltage samples may be filtered utilizing a filter whose weights are obtained as in steps 124 and 126.

For further detail regarding step 134, in an exemplary embodiment, a frequency of power system 204 may be estimated by constructing a system of equations from the plurality of filtered current samples. In an exemplary embodiment, an n^{th} sample I(n) of the plurality of filtered current samples may be equal to A₃ cos (ωᵣn+θ₃)+A₀e^{-nB}^{₀}, where A₃ and θ₃ correspond to a magnitude and a phase of a fundamental component of the current signal, A₀ is amplitude of a decaying DC component of the current signal,

$${B}_{0} = \frac{1}{{f}_{s} τ} ,$$

and τ is a time constant of the decaying DC component. An exemplary system of equations may be constructed from samples

$$I ( n + \frac{N}{2} ) , I ( n - \frac{N}{2} ) , I ( n + \frac{N}{4} ) , I ( n - \frac{N}{4} ) , I ( n + \frac{3 N}{4} ) , and I ( n - \frac{3 N}{4} ) .$$

Solving an exemplary system of equations may eliminate values of A₀, A₃, θ₃, and B₀. By defining

$$y = cos \frac{N}{4} {ω}_{r} ,$$

solving an exemplary system of equations may include obtaining a root yᵣ of a second polynomial defined by the following:

$$8 {λ}_{1} {y}^{3} - 4 {λ}_{2} {y}^{2} + ( 8 {λ}_{2} - 24 {λ}_{1} ) y + \text{} ( 16 {λ}_{1} - 4 {λ}_{2} ) , \text{} where {λ}_{1} = \text{} 4 ( I ( n + \frac{N}{4} ) + I ( n - \frac{N}{4} ) ) - ( I ( n + \frac{N}{2} ) + I ( n - \frac{N}{2} ) ) - 6 I ( n ) and \\ {λ}_{2} = ( I ( n + \frac{N}{4} ) + I ( n - \frac{N}{4} ) ) - ( I ( n + \frac{3 N}{4} ) + I ( n - \frac{3 N}{4} ) ) - 16 I ( n ) . \qquad Equation ( 2 )$$

An exemplary real root of polynomial in Equation (2) may include a value in [−1,1]. An exemplary root of the second polynomial may be obtained by Cardan's method.

For further detail with respect to step 136, in an exemplary embodiment, the estimated fault frequency may be obtained from root yᵣ. In an exemplary embodiment, an independent variable y of the second polynomial may be obtained by change of a variable, that is, an angular frequency ωᵣ of power system 204. As previously stated, an exemplary change of variable is

$$y = cos \frac{N}{4} {ω}_{r} .$$

As a result, an exemplary estimated fault frequency may be obtained according to an operation defined by

$$\frac{2}{N π} {cos}^{- 1} {x}_{r} .$$

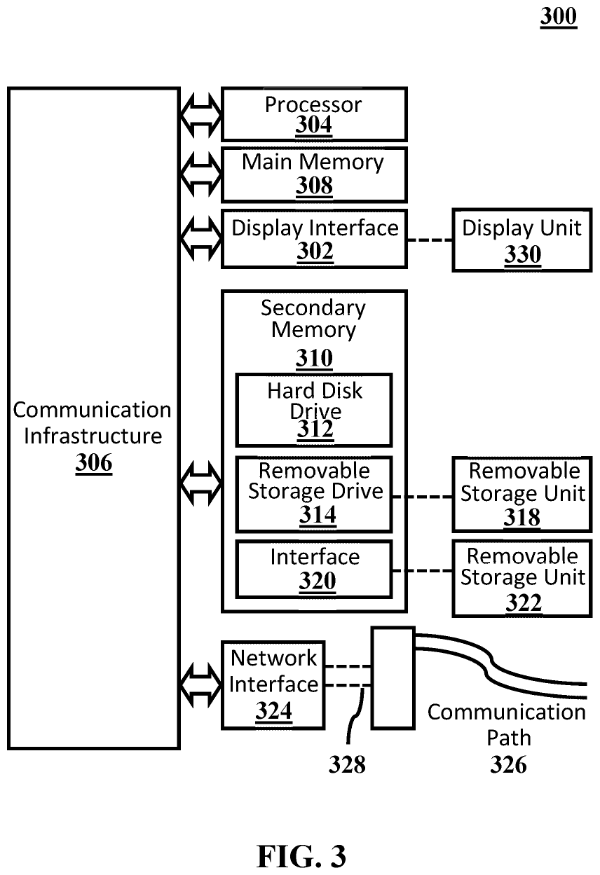

FIG. 3 shows an example computer system 300 in which an embodiment of the present invention, or portions thereof, may be implemented as computer-readable code, consistent with exemplary embodiments of the present disclosure. For example, different steps of method 100 may be implemented in computer system 300 using hardware, software, firmware, tangible computer readable media having instructions stored thereon, or a combination thereof and may be implemented in one or more computer systems or other processing systems. Hardware, software, or any combination of such may embody any of the modules and components in FIGS. 1A-2.

If programmable logic is used, such logic may execute on a commercially available processing platform or a special purpose device. One ordinary skill in the art may appreciate that an embodiment of the disclosed subject matter can be practiced with various computer system configurations, including multi-core multiprocessor systems, minicomputers, mainframe computers, computers linked or clustered with distributed functions, as well as pervasive or miniature computers that may be embedded into virtually any device.

For instance, a computing device having at least one processor device and a memory may be used to implement the above-described embodiments. A processor device may be a single processor, a plurality of processors, or combinations thereof. Processor devices may have one or more processor “cores.”

An embodiment of the invention is described in terms of this example computer system 300. After reading this description, it will become apparent to a person skilled in the relevant art how to implement the invention using other computer systems and/or computer architectures. Although operations may be described as a sequential process, some of the operations may in fact be performed in parallel, concurrently, and/or in a distributed environment, and with program code stored locally or remotely for access by single or multi-processor machines. In addition, in some embodiments the order of operations may be rearranged without departing from the spirit of the disclosed subject matter.

Processor device 304 may be a special purpose (e.g., a graphical processing unit) or a general-purpose processor device. As will be appreciated by persons skilled in the relevant art, processor device 304 may also be a single processor in a multi-core/multiprocessor system, such system operating alone, or in a cluster of computing devices operating in a cluster or server farm. Processor device 304 may be connected to a communication infrastructure 306, for example, a bus, message queue, network, or multi-core message-passing scheme.

In an exemplary embodiment, computer system 300 may include a display interface 302, for example a video connector, to transfer data to a display unit 330, for example, a monitor. Computer system 300 may also include a main memory 308, for example, random access memory (RAM), and may also include a secondary memory 310. Secondary memory 310 may include, for example, a hard disk drive 312, and a removable storage drive 314. Removable storage drive 314 may include a floppy disk drive, a magnetic tape drive, an optical disk drive, a flash memory, or the like. Removable storage drive 314 may read from and/or write to a removable storage unit 318 in a well-known manner. Removable storage unit 318 may include a floppy disk, a magnetic tape, an optical disk, etc., which may be read by and written to by removable storage drive 314. As will be appreciated by persons skilled in the relevant art, removable storage unit 318 may include a computer usable storage medium having stored therein computer software and/or data.

In alternative implementations, secondary memory 310 may include other similar means for allowing computer programs or other instructions to be loaded into computer system 300. Such means may include, for example, a removable storage unit 322 and an interface 320. Examples of such means may include a program cartridge and cartridge interface (such as that found in video game devices), a removable memory chip (such as an EPROM, or PROM) and associated socket, and other removable storage units 322 and interfaces 320 which allow software and data to be transferred from removable storage unit 322 to computer system 300.

Computer system 300 may also include a communications interface 324. Communications interface 324 allows software and data to be transferred between computer system 300 and external devices. Communications interface 324 may include a modem, a network interface (such as an Ethernet card), a communications port, a PCMCIA slot and card, or the like. Software and data transferred via communications interface 324 may be in the form of signals, which may be electronic, electromagnetic, optical, or other signals capable of being received by communications interface 324. These signals may be provided to communications interface 324 via a communications path 326. Communications path 326 carries signals and may be implemented using wire or cable, fiber optics, a phone line, a cellular phone link, an RF link or other communications channels.

In this document, the terms “computer program medium” and “computer usable medium” are used to generally refer to media such as removable storage unit 318, removable storage unit 322, and a hard disk installed in hard disk drive 312. Computer program medium and computer usable medium may also refer to memories, such as main memory 308 and secondary memory 310, which may be memory semiconductors (e.g. DRAMs, etc.).

Computer programs (also called computer control logic) are stored in main memory 308 and/or secondary memory 310. Computer programs may also be received via communications interface 324. Such computer programs, when executed, enable computer system 300 to implement different embodiments of the present disclosure as discussed herein. In particular, the computer programs, when executed, enable processor device 304 to implement the processes of the present disclosure, such as operations in method 100 illustrated by flowcharts of FIGS. 1A-1F discussed above. Accordingly, such computer programs represent controllers of computer system 300. Where an exemplary embodiment of method 100 is implemented using software, the software may be stored in a computer program product and loaded into computer system 300 using removable storage drive 314, interface 320, and hard disk drive 312, or communications interface 324.

Embodiments of the present disclosure also may be directed to computer program products including software stored on any computer useable medium. Such software, when executed in one or more data processing device, causes a data processing device to operate as described herein. An embodiment of the present disclosure may employ any computer useable or readable medium. Examples of computer useable mediums include, but are not limited to, primary storage devices (e.g., any type of random access memory), secondary storage devices (e.g., hard drives, floppy disks, CD ROMS, ZIP disks, tapes, magnetic storage devices, and optical storage devices, MEMS, nanotechnological storage device, etc.).

The embodiments have been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

### EXAMPLE

In this example, a performance of a frequency estimation method (similar to method 100) for frequency estimation in a power system (similar to power system 204) is demonstrated. Different steps of the method are implemented utilizing a protective relay (similar to protective device 202).

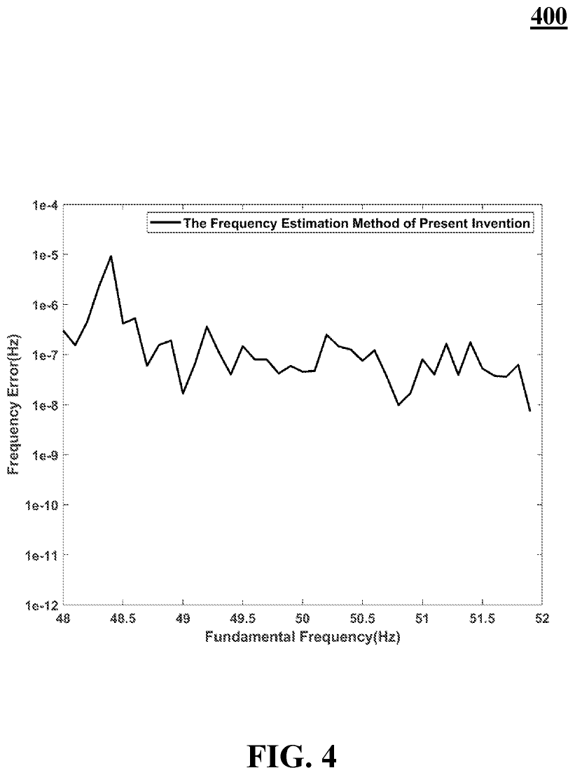

FIG. 4 shows a graph 400 of frequency estimation error in a power system for various fundamental frequencies, consistent with one or more exemplary embodiments of the present disclosure. A fundamental frequency of the power system (similar to frequency fᵣ) is estimated in a range of 48 to 52 Hz, while the nominal frequency (similar to nominal frequency fnon,) is about 50 Hz. The frequency estimation method is applied to a single-tone voltage signal, that is, A cos(ωᵣn+θ) . As FIG. 4 shows, the method precisely estimates the fundamental frequency because estimation error is in a range of 10⁻⁸ to 10⁻⁵ Hz.

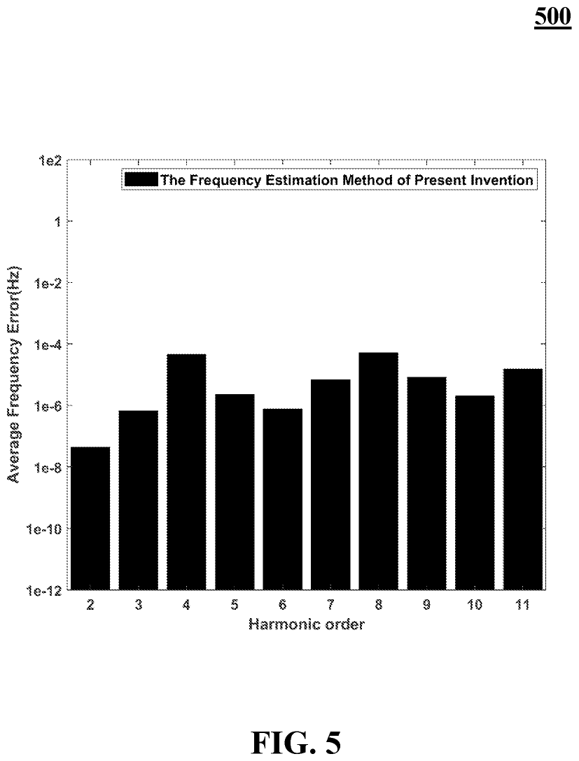

FIG. 5 shows a graph 500 of frequency estimation error in a power system for signals corrupted by various harmonic orders, consistent with one or more exemplary embodiments of the present disclosure. The frequency estimation method is applied to voltage signals that are corrupted by a single harmonic component. A harmonic order is between 2 and 11. Each column in FIG. 5 is an average of estimation errors for fundamental frequencies in the range of 48 to 52 Hz. The estimation error for various harmonic orders is in a range of 10⁻⁸ to 10⁻⁴ Hz. Comparing FIG. 4 with FIG. 5 reveals that an accuracy of the frequency estimation method does not significantly degrades when the voltage signal is subjected to a single harmonic component.

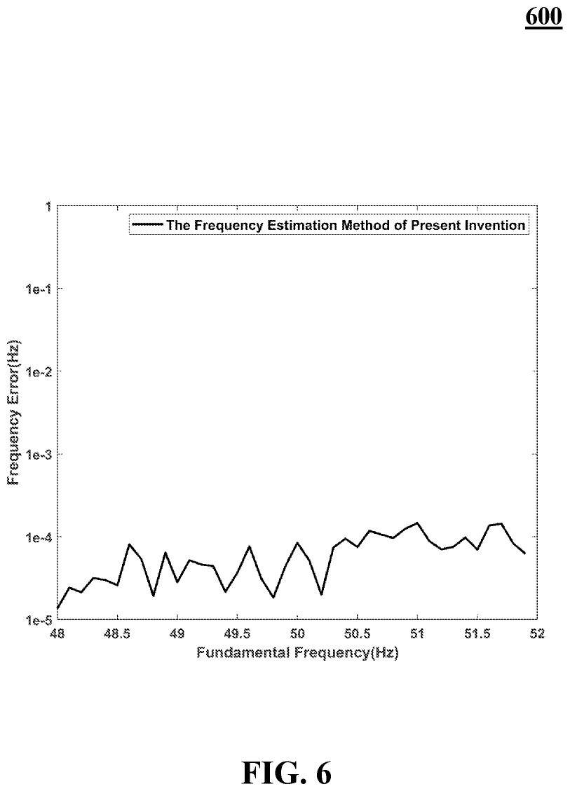

FIG. 6 shows a graph 600 of frequency estimation error in a power system for current signal corrupted by harmonic and decaying DC components, consistent with one or more exemplary embodiments of the present disclosure. The frequency estimation method is applied to a current signal that is corrupted by both harmonic components and decaying DC component. The current signal is subjected to second, third, fourth, fifth, and seventh harmonic orders, each with a respective amplitude and phase. A time constant (similar to time constant τ) of a decaying DC component is about 0.5. The current signal is defined by the following:

$$I ( n ) = 0.5 e ( - n \frac{1}{N \times 50 \times 0.5} ) + cos ( {ω}_{r} n + 2 {0}^{°} ) + 0.05 cos ( 2 {ω}_{r} n + 2 {0}^{°} ) + 0.1 cos ( 3 {ω}_{r} n + 3 {0}^{°} ) + 0.08 cos ( 4 {ω}_{r} n ) + 0.1 cos ( 5 {ω}_{r} n + 1 {5}^{°} ) + 0.07 cos ( 7 {ω}_{r} n - {5}^{°} ) \qquad Equation ( 3 )$$

As in FIG. 6, a frequency estimation error is almost in a range of 10⁻⁵ to 10⁻⁴ Hz for fundamental frequencies in the range of 48 to 52 Hz, that is, a worst-case error is about 0.1 milli Hz.

While the foregoing has described what may be considered to be the best mode and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

The scope of protection is limited solely by the claims that now follow. That scope is intended and should be interpreted to be as broad as is consistent with the ordinary meaning of the language that is used in the claims when interpreted in light of this specification and the prosecution history that follows and to encompass all structural and functional equivalents. Notwithstanding, none of the claims are intended to embrace subject matter that fails to satisfy the requirement of Sections 101, 102, or 103 of the Patent Act, nor should they be interpreted in such a way. Any unintended embracement of such subject matter is hereby disclaimed.

Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various implementations. This is for purposes of streamlining the disclosure, and is not to be interpreted as reflecting an intention that the claimed implementations require more features than are expressly recited in each claim. Rather, as the following claims reflect, inventive subject matter lies in less than all features of a single disclosed implementation. Thus, the following claims are hereby incorporated into the Detailed Description, with each claim standing on its own as a separately claimed subject matter.

While various implementations have been described, the description is intended to be exemplary, rather than limiting and it will be apparent to those of ordinary skill in the art that many more implementations and implementations are possible that are within the scope of the implementations. Although many possible combinations of features are shown in the accompanying figures and discussed in this detailed description, many other combinations of the disclosed features are possible. Any feature of any implementation may be used in combination with or substituted for any other feature or element in any other implementation unless specifically restricted. Therefore, it will be understood that any of the features shown and/or discussed in the present disclosure may be implemented together in any suitable combination. Accordingly, the implementations are not to be restricted except in light of the attached claims and their equivalents. Also, various modifications and changes may be made within the scope of the attached claims.

What is claimed is:

1. A method for frequency estimation in a power system, the method comprising:
detecting, utilizing a protective device, a condition of the power system, the condition comprising one of a normal condition and a fault condition;
applying a first estimation process to a voltage signal of the power system responsive to the normal condition being detected, applying the first estimation process comprising:
obtaining, utilizing the protective device, a plurality of voltage samples by sampling the voltage signal; and
obtaining, utilizing one or more processors, an estimated normal frequency of the power system by:
generating a first plurality of shifted voltage samples by multiplying an n^{th} sample of the plurality of voltage samples by e^{jω}^{ₙₒₘ}ⁿ, where nϵ[0, N−1], N is a number of the plurality of voltage samples, and ωₙₒᵣₘ is a nominal angular frequency of the power system;
generating a plurality of filtered voltage samples by filtering the first plurality of shifted voltage samples;
generating a second plurality of shifted voltage samples by multiplying an n^{th} sample of the plurality of filtered voltage samples by e^{-jω}^{ₙₒₘ}ⁿ;
obtaining a root xᵣ of a first polynomial defined by the following:
$$2 Im \{ V ( n - \frac{N}{2} ) \} {x}^{3} - 2 {μ}_{1} {x}^{2} - ( {μ}_{1} + Im \{ V ( n - \frac{N}{2} ) \} ) x + {μ}_{1} + {μ}_{2}$$
where:
V(n) is an n^{th} sample of the second plurality of shifted voltage samples,
$${μ}_{1} = \frac{1}{2} ( Im \{ V ( n + \frac{N}{4} ) \} + Im \{ V ( n - \frac{N}{4} ) \} ) ,$$
$${μ}_{2} = \frac{1}{4} ( Im \{ V ( n + \frac{N}{2} ) \} + Im \{ V ( n - \frac{N}{2} ) \} + 2 Im \{ V ( n ) \} ) ,$$
and
Im{V(.)} returns an imaginary part of V(.); and
calculating the estimated normal frequency according to an operation defined by
$$\frac{2}{N π} {cos}^{- 1} {x}_{r} ;$$
and
applying a second estimation process to a current signal of the power system responsive to the fault condition being detected, applying the second estimation process comprising:
obtaining, utilizing the protective device, a plurality of current samples by sampling the current signal; and
obtaining, utilizing the one or more processors, an estimated fault frequency of the power system by:
generating a plurality of filtered current samples by filtering the plurality of current samples;
obtaining a root yr of a second polynomial defined by the following:
8λ₁y³−4λ₂y²+(8λ₂−24λ₁)y+(16λ₁−4λ₂)
where:
$${λ}_{1} = 4 ( I ( n + \frac{N}{4} ) + I ( n - \frac{N}{4} ) ) - ( I ( n + \frac{N}{2} ) + I ( n - \frac{N}{2} ) ) - 6 I ( n ) ,$$
$${λ}_{2} = 9 ( I ( n + \frac{N}{4} ) + I ( n - \frac{N}{4} ) ) - ( I ( n + \frac{3 N}{4} ) + I ( n - \frac{3 N}{4} ) ) - 16 I ( n ) ,$$
and
I(n) is an n^{th} sample of the plurality of filtered current samples; and
calculating the estimated frequency according to an operation defined by
$$\frac{2}{N π} {cos}^{- 1} {y}_{r} .$$

2. A method for frequency estimation in a power system, the method comprising:
detecting, utilizing a protective device, a condition of the power system, the condition comprising one of a normal condition and a fault condition;
applying a first estimation process to a voltage signal of the power system responsive to the normal condition being detected; and
applying a second estimation process to a current signal of the power system responsive to the fault condition being detected.

3. The method of claim 2, wherein applying the first estimation process comprises:
obtaining, utilizing the protective device, a plurality of voltage samples by sampling the voltage signal; and
obtaining, utilizing one or more processors, an estimated normal frequency of the power system by:
generating a first plurality of shifted voltage samples by multiplying an n^{th} sample of the plurality of voltage samples by e^{jω}^{ₙₒₘ}ⁿ, where nϵ[0, N−1], N is a number of the plurality of voltage samples, and ωₙₒₘ is a nominal angular frequency of the power system;
generating a plurality of filtered voltage samples by filtering the first plurality of shifted voltage samples;
generating a second plurality of shifted voltage samples by multiplying an n^{th} sample of the plurality of filtered voltage samples by e^{-jω}^{ₙₒₘ}ⁿ;
obtaining a root xᵣ of a first polynomial defined by the following:
$$2 Im \{ V ( n - \frac{N}{2} ) \} {x}^{3} - 2 {μ}_{1} {x}^{2} - ( {μ}_{1} + Im \{ V ( n - \frac{N}{2} ) \} ) x + {μ}_{1} + {μ}_{2}$$
where:
V(n) is an n^{th} sample of the second plurality of shifted voltage samples,
$${μ}_{1} = \frac{1}{2} ( Im \{ V ( n + \frac{N}{4} ) \} + Im \{ V ( n - \frac{N}{4} ) \} ) ,$$
$${μ}_{2} = \frac{1}{4} ( Im \{ V ( n + \frac{N}{2} ) \} + Im \{ V ( n - \frac{N}{2} ) \} + 2 Im \{ V ( n ) \} ) ,$$
and
Im{V(.)} returns an imaginary part of V(.); and
calculating the estimated normal frequency according to an operation defined
$$by \frac{2}{N π} {cos}^{- 1} {x}_{r} .$$

4. The method of claim 3, wherein applying the second estimation process comprises:
obtaining, utilizing the protective device, a plurality of current samples by sampling the current signal; and
obtaining, utilizing the one or more processors, an estimated fault frequency of the power system by:
generating a plurality of filtered current samples by filtering the plurality of current samples;
obtaining a root yᵣ of a second polynomial defined by the following:
8λ₁y³−4λ₂y²+(8λ₂−24λ₁)y+(16λ₁−4λ₂)
where:
$${λ}_{1} = 4 ( I ( n + \frac{N}{4} ) + I ( n - \frac{N}{4} ) ) - ( I ( n + \frac{N}{2} ) + I ( n - \frac{N}{2} ) ) - 6 I ( n ) ,$$
$${λ}_{2} = 9 ( I ( n + \frac{N}{4} ) + I ( n - \frac{N}{4} ) ) - ( I ( n + \frac{3 N}{4} ) + I ( n - \frac{3 N}{4} ) ) - 16 I ( n ) ,$$
and
I(n) is an n^{th} sample of the plurality of filtered current samples; and
calculating the estimated fault frequency according to an operation defined by
$$\frac{2}{N π} {cos}^{- 1} {y}_{r} .$$

5. The method of claim 4, wherein filtering each of the first plurality of shifted voltage samples and the plurality of current samples comprises obtaining a first plurality of weights of a filter by solving an optimization problem, wherein:
an objective function of the optimization problem comprises a magnitude of a frequency response of the filter at a zero angular frequency; and
an m^{th} constraint of the optimization problem comprises a magnitude of the frequency response at an angular frequency corn being less than a magnitude threshold, where:
mϵ[1, M],
M is a number of constraints in the optimization problem, and
the angular frequency ωₘ is larger than a frequency threshold ωₜₕ.

6. The method of claim 5, wherein filtering the each of the first plurality of shifted voltage sampl1es and the plurality of current samples further comprises obtaining a second plurality of weights according to an operation defined by h(n)*h(n), where h(n) is an n^{th} weight of the first plurality of weights and * is a convolution operator.

7. The method of claim 5, wherein solving the optimization problem comprises setting a value of the angular frequency ωₘ to
$${ω}_{th} + ( m - 1 ) \frac{π}{{f}_{s}} ,$$
where fₛ is a sampling frequency of the protective device.

8. The method of claim 7, wherein setting the value of the angular frequency ωₘ comprises setting the value of the frequency threshold ωₜₕ to 2ωₙₚₘ.

9. The method of claim 5, wherein solving the optimization problem comprises setting the magnitude threshold to 10⁻⁵.

10. The method of claim 2, wherein detecting the condition comprises one of:
detecting the fault condition responsive to an electrical fault being detected in the power system; or
detecting the normal condition responsive to the electrical fault not being detected.

11. A system for frequency estimation in a power system, the system comprising:
a protective device configured to:
detect a condition of the power system, the condition comprising one of a normal condition and a fault condition;
obtain a plurality of voltage samples by sampling a voltage signal of the power system responsive to the normal condition being detected; and
obtain a plurality of current samples by sampling a current signal of the power system responsive to the fault condition being detected;
a memory having processor-readable instructions stored therein; and
one or more processors configured to access the memory and execute the processor-readable instructions, which, when executed by the one or more processors configures the one or more processors to perform a method, the method comprising:
applying a first estimation process to the voltage signal responsive to the normal condition being detected; and
applying a second estimation process to the current signal responsive to the fault condition being detected.

12. The system of claim 11, wherein applying the first estimation process comprises:
obtaining an estimated normal frequency of the power system by:
generating a first plurality of shifted voltage samples by multiplying an n^{th} sample of the plurality of voltage samples by e^{jω}^{ₙₒₘ}ⁿ, where nϵ[0, N −1], N is a number of the plurality of voltage samples, and ωₙₒᵣₘ is a nominal angular frequency of the power system;
generating a plurality of filtered voltage samples by filtering the first plurality of shifted voltage samples;
generating a second plurality of shifted voltage samples by multiplying an n^{th} sample of the plurality of filtered voltage samples by e^{jω}^{ₙₒₘ}ⁿ;
obtaining a root xᵣ of a first polynomial defined by the following:
$$2 Im \{ V ( n - \frac{N}{2} ) \} {x}^{3} - 2 {μ}_{1} {x}^{2} - ( {μ}_{1} + Im \{ V ( n - \frac{N}{2} ) \} ) x + {μ}_{1} + {μ}_{2}$$
where:
V (n) is an n^{th} sample of the second plurality of shifted voltage samples,
$${μ}_{1} = \frac{1}{2} ( Im \{ V ( n + \frac{N}{4} ) \} + Im \{ V ( n - \frac{N}{4} ) \} ) ,$$
$${μ}_{2} = \frac{1}{4} ( Im \{ V ( n + \frac{N}{2} ) \} + Im \{ V ( n - \frac{N}{2} ) \} + 2 Im \{ V ( n ) \} ) ,$$
and
Im{V(.)} returns an imaginary part of V(.); and
calculating the estimated normal frequency according to an operation defined by
$$\frac{2}{N π} {cos}^{- 1} {x}_{r} .$$

13. The system of claim 12, wherein applying the second estimation process comprises:
obtaining an estimated fault frequency of the power system by:
generating a plurality of filtered current samples by filtering the plurality of current samples;
obtaining a root yr of a second polynomial defined by the following:
8λ₁y³−4λ₂y²+(8λ₂−24λ₁)y+(16λ₁−4λ₂)
where:
$${λ}_{1} = 4 ( I ( n + \frac{N}{4} ) + I ( n - \frac{N}{4} ) ) - ( I ( n + \frac{N}{2} ) + I ( n - \frac{N}{2} ) ) - 6 I ( n ) ,$$
$${λ}_{2} = 9 ( I ( n + \frac{N}{4} ) + I ( n - \frac{N}{4} ) ) - ( I ( n + \frac{3 N}{4} ) + I ( n - \frac{3 N}{4} ) ) - 16 I ( n ) ,$$
and
I(n) is an n^{th} sample of the plurality of filtered current samples; and
calculating the estimated fault frequency according to an operation defined by
$$\frac{2}{N π} {cos}^{- 1} {y}_{r} .$$

14. The system of claim 13, wherein filtering each of the first plurality of shifted voltage samples and the plurality of current samples comprises obtaining a first plurality of weights of a filter by solving an optimization problem, wherein:
an objective function of the optimization problem comprises a magnitude of a frequency response of the filter at a zero angular frequency; and
an m^{th} constraint of the optimization problem comprises a magnitude of the frequency response at an angular frequency corn being less than a magnitude threshold, where:
mϵ[1, M],
M is a number of constraints in the optimization problem, and
the angular frequency corn is larger than a frequency threshold ωₜₕ.

15. The system of claim 14, wherein filtering the each of the first plurality of shifted voltage samples and the plurality of current samples further comprises obtaining a second plurality of weights according to an operation defined by h(n)*h(n) , where h(n) is an n^{th} weight of the first plurality of weights and * is a convolution operator.

16. The system of claim 14, wherein solving the optimization problem comprises setting a value of the angular frequency ωₘ to
$${ω}_{th} + ( m - 1 ) \frac{π}{{f}_{s}} ,$$
where A is a sampling frequency of the protective device.

17. The system of claim 14, wherein setting the value of the angular frequency corn comprises setting the value of the frequency threshold ωₜₕ to 2ωₙₒₘ.

18. The system of claim 14, wherein solving the optimization problem comprises setting the magnitude threshold to 10⁻⁵.

19. The system of claim 11, wherein:
the fault condition corresponds to presence of an electrical fault in the power system; and
the normal condition corresponds to absence of the electrical fault in the power system.
